(19) United States
(12) Patent Application Publication
(10) Pub. No.: US 2026/0013108 A1
(43) Pub. Date: Jan. 8, 2026

(54) INTEGRATED CIRCUIT DEVICES

(71) Applicant: Samsung Electronics Co., Ltd., Suwon-si (KR)

(72) Inventor: HYUNGKI CHO, Suwon-si (KR)

(21) Appl. No.: 19/024,710

(22) Filed: Jan. 16, 2025

(30) Foreign Application Priority Data
Jul. 2, 2024 (KR) 10-2024-0087044

(51) Int. Cl. H10B 12/00

(52) U.S. Cl. CPC H10B 12/33; H10B 12/05

(57) ABSTRACT

An integrated circuit device comprising: contacts spaced apart from each other in an insulating layer; a cell trench extending in the insulating layer, wherein the cell trench extends in a second direction; an interlayer insulating film adjacent the cell trench; a pair of gate electrodes that are respectively in contact with opposite sidewalls of the interlayer insulating film; a channel layer in the cell trench, wherein the channel layer extends around the pair of gate electrodes; a gate insulating layer between the channel layer and the pair of gate electrodes; and a conductive line on the channel layer, wherein an upper surface of the pair of gate electrodes is at a first distance from an upper surface of the insulating layer and an upper surface of the interlayer insulating film is at a second distance, which is different from the first distance, from the upper surface of the insulating layer.

### CROSS-REFERENCE TO RELATED APPLICATIONS

This application is based on and claims priority under 35 U.S.C. § 119 to Korean Patent Application No. 10-2024-0087044, filed on Jul. 2, 2024, in the Korean Intellectual Property Office, the disclosure of which is incorporated by reference herein in its entirety.

### BACKGROUND OF THE INVENTION

The inventive concept relates to semiconductor devices, such as an integrated circuit (IC) device. More specifically, the inventive concept may relate to an IC device including a vertical channel transistor.

With the downscaling of semiconductor devices, the size of dynamic random access memory (DRAM) devices is also decreasing. In a DRAM device having a one-transistor one-capacitor (1T-1C) structure in which one capacitor is connected to one transistor, there is a problem in which a leakage current through a channel region gradually increases as devices are miniaturized. A transistor using an oxide semiconductor material as a channel layer has been proposed to reduce a leakage current.

### SUMMARY OF THE INVENTION

The inventive concept provides an integrated circuit (IC) device having improved (excellent) operating characteristics and improved reliability.

The technical objectives of the inventive concept are not limited to the above disclosure; other objectives may become apparent to those of ordinary skill in the art based on the following descriptions.

According to an aspect of the inventive concept, there is provided an IC device.

The IC device includes an insulating layer; contacts in the insulating layer, wherein the contacts are spaced apart from each other by a predetermined distance in a first direction; a cell trench extending in the insulating layer, wherein the cell trench extends in a second direction that intersects the first direction; an interlayer insulating film adjacent the cell trench; a pair of gate electrodes that are respectively in contact with opposite sidewalls of the interlayer insulating film in the first direction; a channel layer in the cell trench, wherein the channel layer extends around the pair of gate electrodes; a gate insulating layer between the channel layer and the pair of gate electrodes; and a conductive line on the channel layer, wherein the conductive line extends in the first direction and is in contact with the channel layer, wherein an upper surface of the pair of gate electrodes is at a first distance from an upper surface of the insulating layer in a third direction that intersects the first direction and the second direction, wherein an upper surface of the interlayer insulating film is at a second distance from the upper surface of the insulating layer in the third direction, and wherein the first distance is different from the second distance.

According to some aspects of the inventive concept, there is provided an IC device including an insulating layer; interlayer insulating films on the insulating layer, wherein the interlayer insulating films are spaced apart from each other in a first direction and extend in a second direction that intersects the first direction; a pair of gate electrodes that are spaced apart each other in the first direction on the insulating layer, wherein an interlayer insulating film from among the interlayer insulating films is between the pair of gate electrodes; a gate insulating layer on an upper surface of the interlayer insulating film and an upper surface and a sidewall of the pair of gate electrodes; a channel layer extending along at least a portion of the gate insulating layer with a uniform thickness; and a conductive line on the channel layer, wherein the conductive line extends in the first direction and is in contact with the channel layer, wherein at least one from among the pair of gate electrodes comprises a first portion and a second portion, wherein the first portion has a bar shape and is in direct contact with a sidewall of the interlayer insulating film, wherein the second portion is integrally connected to the first portion, and wherein the second portion extends farther than the upper surface of the interlayer insulating film from an upper surface of the insulating layer in a third direction that intersects the first direction and the second direction.

According to some aspects of the inventive concept, there is provided an IC device including an insulating layer; interlayer insulating films on the insulating layer, wherein the interlayer insulating films are spaced apart from each other in a first direction and extend in a second direction that intersects the first direction; contacts in the insulating layer, wherein the contacts are spaced apart from each other in the first direction; a pair of gate electrodes that are spaced apart from each other in the first direction on the insulating layer, wherein an interlayer insulating film from among the interlayer insulating films is between the pair of gate electrodes; a gate insulating layer on an upper surface of the interlayer insulating film and an upper surface and a sidewall of the pair of gate electrodes; a channel layer extending along at least a portion of the gate insulating layer with a uniform thickness, wherein the channel layer is in contact with at least a portion of an upper surface of each of the contacts; and a conductive line on the channel layer, wherein the conductive line extends in the first direction and is in contact with the channel layer, wherein the channel layer comprises an oxide semiconductor material, wherein a length of at least one from among the pair of gate electrodes in a third direction is greater than a length of the interlayer insulating film in the third direction, and wherein the third direction intersects the first direction and the second direction.

### BRIEF DESCRIPTION OF THE DRAWINGS

Embodiments will be more clearly understood from the following detailed description taken in conjunction with the accompanying drawings in which:

FIG. 1 is a cross-sectional view of an integrated circuit (IC) device according to embodiments; and

FIGS. 2 to 19 are cross-sectional views of a process sequence of a method of manufacturing an IC device, according to embodiments.

### DETAILED DESCRIPTION OF THE INVENTION

Hereinafter, embodiments will be described in detail with reference to the accompanying drawings. The same reference numerals are used to denote the same elements in the drawings unless clearly described otherwise, and repeated descriptions thereof may be omitted.

While embodiments can be modified in various ways and take on various alternative forms, specific embodiments are shown in the drawings and described in detail below as examples. There is no intent to limit the inventive concept to the particular forms disclosed. On the contrary, the inventive concept is to cover all modifications, equivalents, and alternatives falling within the scope of the appended claims. In the following detailed description of embodiments, a detailed description of known techniques incorporated therein may be omitted not to unnecessarily obscure the embodiments.

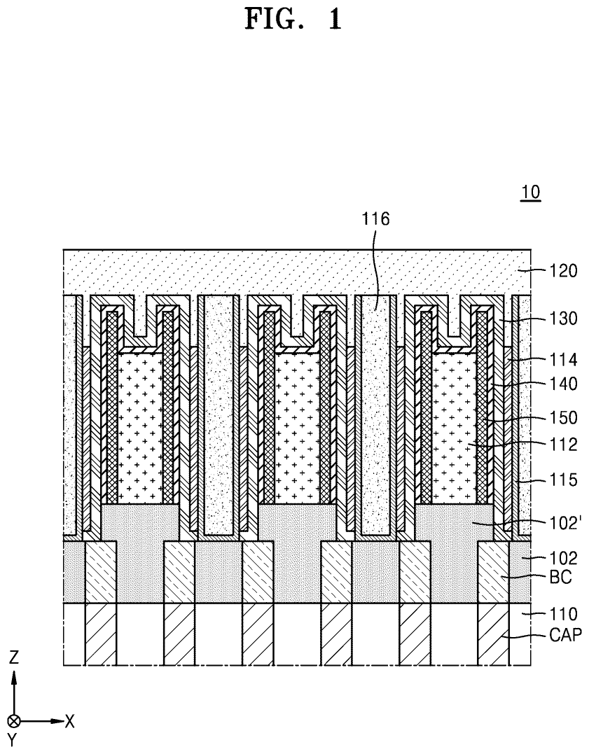

FIG. 1 is a cross-sectional view of an integrated circuit (IC) device 10 according to embodiments.

Referring to FIG. 1, the IC device 10 according to the embodiments may include a conductive line 120, a first interlayer insulating film 112, a gate electrode 150, a gate insulating layer 140, a channel layer 130, a second interlayer insulating film 114, a third interlayer insulating film 116, a contact BC, and a capacitor structure CAP.

Capacitor structures CAP may be provided in the form of pillars extending in a third direction (Z direction), without being limited thereto. A plurality of capacitor structures CAP may be arranged in a matrix form apart from each other in a first direction (X direction) and a second direction (Y direction) that intersects with the first direction (X direction). The capacitor structures CAP may be (electrically) connected to the channel layer 130 through the contact BC. Although the illustration is omitted for brevity, each of the capacitor structures CAP may include a lower electrode, a capacitor dielectric layer, and an upper electrode. In some embodiments, the first direction and the second direction may be parallel with an upper surface of the lower insulating film 110. The third direction may be perpendicular to the upper surface of the lower insulating film 110.

In some embodiments, an IC device (e.g., the IC device 10) according to embodiments may be provided as dynamic RAM (DRAM) due to the capacitor structures CAP. For example, the capacitor structures CAP may store data (charges) in the capacitor dielectric layer by using the occurrence of a potential difference between the lower electrode and the upper electrode.

Each of the lower electrode and the upper electrode of the capacitor structure CAP may include, for example, doped polysilicon, a metal, a conductive metal nitride, a conductive metal silicide, a conductive metal oxide, and/or a combination thereof. For example, each of the lower electrode and the upper electrode may include doped polysilicon, aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminide (TiAl), titanium aluminum nitride (TiAlN), titanium silicide (TiSi), titanium silicon nitride (TiSiN), tantalum silicide (TaSi), tantalum silicon nitride (TaSiN), ruthenium titanium nitride (RuTiN), nickel silicide (NiSi), cobalt silicide (CoSi), iridium oxide (IrOx), ruthenium oxide (RuOx), and/or a combination thereof, without being limited thereto.

The capacitor dielectric layer of the capacitor structure CAP may include, for example, silicon oxide, silicon oxynitride, a high-k dielectric material having a higher dielectric constant than silicon oxide, and/or a combination thereof. The high-k dielectric material may include, for example, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃) and/or a combination thereof, without being limited thereto.

Contacts BC may be formed on a lower insulating film 110 and located between second insulating layers 102. Each of the contacts BC may overlap at least a portion of the channel layer 130 in the third direction (Z direction). A plurality of contacts BC may be arranged in a matrix form apart from each other in the first direction (X direction) and the second direction (Y direction). However, the inventive concept is not limited thereto, and the arrangement of the contacts BC is not limited as long as each of the contacts BC is (electrically) connected to the channel layer 130. In some embodiments, the plurality of contacts BC may be arranged in a honeycomb form. The contacts BC may at least partially overlap the capacitor structures CAP in the third direction (Z direction).

Each of the contacts BC may include, for example, doped polysilicon, a metal, a conductive metal nitride, a conductive metal silicide, a conductive metal oxide, and/or a combination thereof. For example, each of the contacts BC may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx and/or a combination thereof, without being limited thereto.

The first interlayer insulating film 112 may be formed on an additional insulating layer 102′. The first interlayer insulating film 112 may be between a pair of (adjacent) gate electrodes 150, and an upper surface (e.g., a top surface) of the first interlayer insulating film 112 may be at a lower level than an upper surface (e.g., a top surface) of the gate electrode 150 in the third direction (Z direction). First interlayer insulating films 112 may each extend in the second direction (Y direction) and be (equidistantly) apart from each other in the first direction (X direction). In some embodiments, the first interlayer insulating films 112 may be arranged to be spaced apart from each other by an equal (e.g., a substantially equal) distance in the first direction (X direction). Thus, the first interlayer insulating film 112 may form fin-type insulating patterns, which each extend in the second direction (Y direction) and are apart from each other (in the first direction (X direction)). The term, “level”, may be a relative location (e.g., distance) from a reference point (a lower surface of the lower insulating film 110) in the third direction (Z direction). A farther distance from the lower surface of the lower insulating film 110 may be referred to as a higher level. A closer distance from the lower surface of the lower insulating film 110 may be referred to as a lower level.

In some embodiments, the upper surface (e.g., the top surface) of the first interlayer insulating film 112 may be covered by the gate insulating layer 140. For example, the gate insulating layer 140 may be on (may overlap in the third direction) the upper surface of the first interlayer insulating film 112. In some embodiments, the upper surface (e.g., the top surface) of the first interlayer insulating film 112 may be apart from a lower surface (e.g., a bottom surface) of the conductive line 120 (by the gate insulating layer 140 and/or the channel layer 130).

The first interlayer insulating film 112 may include, for example, silicon oxide, silicon oxynitride, silicon nitride, and/or a low-k dielectric material having a lower dielectric constant than silicon oxide, without being limited thereto.

A pair of (adjacent) gate electrodes 150, which are symmetrical to each other, may be opposite to each other with the first interlayer insulating film 112 therebetween. For example, the gate electrodes 150 may extend along both (opposite) sidewalls of the first interlayer insulating film 112 in the third direction (Z direction). In this case, a length by which the gate electrodes 150 extend in the third direction (Z direction) may be greater than a length of the first interlayer insulating film 112 in the third direction (Z direction).

In some embodiments, the gate electrodes 150 may include a pair of gate electrodes 150, which are apart from each other in the first direction (X direction). The pair of gate electrodes 150 may be opposite to each other across the first interlayer insulating film 112. For example, one gate electrode 150 may extend along a first side surface of the first interlayer insulating film 112, and another gate electrode 150 may extend along a second side surface that is opposite the first side surface of the first interlayer insulating film 112 (in the first direction D1 (X direction)). One gate electrode 150 (among the pair of gate electrodes 150) may function as a first word line of an IC device (e.g., the IC device 10) according to some embodiments, and another gate electrode 150 (among the pair of gate electrodes 150) may function as a second word line of the IC device (e.g., the IC device 10) according to some embodiments.

In some embodiments, upper portions of the gate electrodes 150, which protrude over the first interlayer insulating film 112 in the third direction (Z direction), may be surrounded by the gate insulating layer 140 and the channel layer 130. For example, the gate insulating layer 140 and the channel layer 130 may be on (may extend around) the upper portions of the gate electrodes 150.

Each of the gate electrodes 150 may include, for example, doped polysilicon, a metal, a conductive metal nitride, a conductive metal silicide, a conductive metal oxide, and/or a combination thereof. For example, each of the gate electrodes 150 may include doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx and/or a combination thereof, without being limited thereto.

The gate insulating layer 140 may be (stacked) on the gate electrodes 150. For example, the gate insulating layer 140 may conformally extend along a profile of the gate electrodes 150. The gate insulating layer 140 may be between the gate electrodes 150 and the channel layer 130 described below. In some embodiments, the gate insulating layer 140 may further extend along the upper surface (e.g., the top surface) of the first interlayer insulating film 112.

The gate insulating layer 140 may include, for example, silicon oxide, silicon oxynitride, a high-k dielectric material having a higher dielectric constant than silicon oxide, and/or a combination thereof. The high-k dielectric material may include, for example, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), and/or a combination thereof, without being limited thereto.

In some embodiments, an IC device (e.g., the IC device 10) according to some embodiments may be provided as ferroelectric RAM (FeRAM) due to the gate insulating layer 140.

In some embodiments, the gate insulating layer 140 may include a ferroelectric material, such as barium titanate (BaTiO₃), lead zirconate titanate (PbZrTiO₃ or PZT), strontium bismuth tantalate (SrBi₂Ta₂O₉ or STB), bismuth iron oxide (BiFeO₃ or BFO), and hafnium oxide (HfO₂).

The channel layer 130 may be (stacked) on the gate insulating layer 140. The channel layer 130 may fill at least a portion of the first interlayer insulating film 112. For example, the channel layer 130 may extend along profiles of the gate electrodes 150 and the gate insulating layer 140. Thus, each of the gate electrodes 150 and the gate insulating layer 140 may be between the first interlayer insulating film 112 and the channel layer 130.

The channel layer 130 may be (electrically) connected to the conductive line 120. In some embodiments, a plurality of channel layers 130 may be arranged in a matrix form apart from each other in the first direction (X direction) and the second direction (Y direction).

In a semiconductor memory device according to some embodiments, a channel layer 130 may include a first source/drain region and a second source/drain region, which are arranged in a vertical direction (e.g., the third direction (Z direction) that intersects with the first direction (X direction) and the second direction (Y direction)). For example, a lower portion of the channel layer 130 may function as the first source/drain region, an upper portion of the channel layer 130 may function as the second source/drain region, and a portion of the channel layer 130 between the first source/drain region and the second source/drain region may function as a channel region.

The channel layer 130 may include, for example, a semiconductor material. In some embodiments, the channel layer 130 may include an oxide semiconductor material. The oxide semiconductor material may reduce a leakage current of the semiconductor memory device. The oxide semiconductor material may include, for example, indium gallium zinc oxide (InxGayZnzO or IGZO), indium gallium silicon oxide (InxGaySizO or IGSO), indium tin zinc oxide (InxSnyZnzO or ITZO), indium zinc oxide (InxZnyO or IZO), zinc oxide (ZnxO or ZnO), zinc tin oxide (ZnxSnyO or ZTO), zinc oxynitride (ZnxOyN or ZnON), zirconium zinc tin oxide (ZrxZnySnzO or ZZTO), tin oxide (SnxO or SnO), hafnium indium zinc oxide (HfxInyZnzO or HIZO), gallium zinc tin oxide (GaxZnySnzO or GZTO), aluminum zinc tin oxide (AlxZnySnzO or AZTO), ytterbium gallium zinc oxide (YbxGayZnzO or YGZO), indium gallium oxide (InxGayO or IGO), and/or a combination thereof.

In some embodiments, the channel layer 130 may include an elemental semiconductor material, such as silicon (Si), germanium (Ge), or a material doped therein. In some embodiments, the channel layer 130 may include a Group IV-IV compound semiconductor and/or a Group III-V compound semiconductor. The Group IV-IV compound semiconductor may include, for example, a binary compound or a ternary compound, which includes at least two of carbon (C), silicon (Si), germanium (Ge), and tin (Sn), or a compound obtained by doping a Group IV element into the binary compound or the ternary compound.

In some embodiments, the channel layer 130 may include a two-dimensional (2D) semiconductor material. The 2D semiconductor material may include, for example, graphene, carbon nanotubes, transition metal dichalcogenide (TMD), and/or a combination thereof. The TMD may include, for example, a metal element selected from molybdenum (Mo), tungsten (W), niobium (Nb), vanadium (V), tantalum (Ta), titanium (Ti), zirconium (Zr), hafnium (Hf), technetium (Tc), rhenium (Re), copper (Cu), gallium (Ga), indium (In), tin (Sn), germanium (Ge), and lead (Pb) and a chalcogen element selected from sulfur(S), selenium (Se), and tellurium (Te).

The channel layer 130 may include a single layer or multiple layer of the semiconductor materials described above. For example, the channel layer 130 may include IGZO.

The second interlayer insulating film 114 may be formed to be in contact with one sidewall of the channel layer 130. For example, the second interlayer insulating film 114 may be between the channel layer 130 and a capping insulating film 115 (in the first direction (X direction)) and extend in the third direction (Z direction). A plurality of channel layers 130, which are arranged in a matrix form apart from each other, may be separated from each other by the second interlayer insulating film 114. In some embodiments, an upper surface (e.g., a top surface) of the second interlayer insulating film 114 may be at a lower level than an upper surface (e.g., a top surface) of the channel layer 130. That is, the second interlayer insulating film 114 may cover (e.g., overlap in the first direction (X direction)) only a portion of a side surface of the channel layer 130. In some embodiments, the upper surface (e.g., the top surface) of the second interlayer insulating film 114 may be at a lower level than (an upper surface (e.g., a top surface) of) the capping insulating film 115. That is, the second interlayer insulating film 114 may cover (e.g., overlap in the first direction (X direction)) only a portion of a side surface of the capping insulating film 115.

Each of the second interlayer insulating film 114 and the third interlayer insulating film 116 may include, for example, silicon oxide, silicon oxynitride, silicon nitride, and/or a low-k dielectric material having a lower dielectric constant than silicon oxide, without being limited thereto. The capping insulating film 115 may include, for example, a different material from the second interlayer insulating film 114 and the third interlayer insulating film 116. The capping insulating film 115 may include, for example, aluminum oxide (AlO).

In embodiments, the upper surface (e.g., the top surface) of the second interlayer insulating film 114 may be at a higher vertical level than the upper surface (e.g., the top surface) of the first interlayer insulating film 112. However, the inventive concept is not limited thereto. In some embodiments, the upper surface (e.g., the top surface) of the second interlayer insulating film 114 may be at a lower vertical level than the upper surface (e.g., the top surface) of the first interlayer insulating film 112 and be at the same vertical level as the upper surface (e.g., the top surface) of the first interlayer insulating film 112.

The conductive line 120 may be formed to fill a space between the channel layers 130 and a space between the channel layer 130 and the third interlayer insulating film 116. For example, the conductive line 120 may extend lengthwise in the first direction (X direction). A plurality of conductive lines 120 may each extend in the first direction (X direction) and be (equidistantly) apart from each other in the second direction (Y direction), which intersects with the first direction (X direction). In some embodiments, the conductive lines 120 may be arranged to be spaced apart from each other by an equal (e.g., a substantially equal) distance in the second direction (Y direction). The conductive line 120 may function as a bit line of an IC device (e.g., the IC device 10) according to some embodiments.

The conductive line 120 may include, for example, doped polysilicon, metal, conductive metal nitride, conductive metal silicide, conductive metal oxide, and/or a combination thereof. For example, the conductive line 120 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx and/or a combination thereof, without being limited thereto. In some embodiments, the conductive line 120 may include a 2D semiconductor material. The 2D semiconductor material may include, for example, graphene, carbon nanotubes, and/or a combination thereof. The conductive line 120 may include a single layer or multiple layer of the semiconductor materials described above.

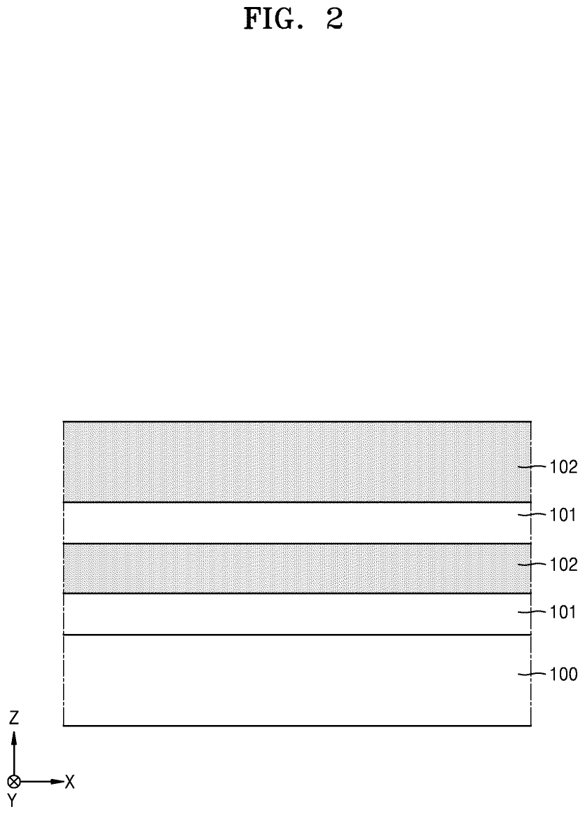

Hereinafter, a method of manufacturing the IC device 10, according to embodiments, is described with reference to FIGS. 2 to 19.

FIGS. 2 to 19 are cross-sectional views of a process sequence of a method of manufacturing an IC device 10, according to embodiments.

Referring to FIG. 2, a first substrate 100 and a first insulating layer 101 and a second insulating layer 102, which are alternately stacked on the first substrate 100, may be provided.

The first substrate 100 may have a structure in which a base substrate and an epitaxial layer are stacked, but the inventive concept is not limited thereto. The first substrate 100 may include, for example, a silicon substrate, a gallium arsenic substrate, a silicon germanium substrate, and/or a semiconductor-on-insulator (SOI) substrate.

In embodiments, the first insulating layer 101 may include, for example, silicon oxide (SiO). In embodiments, the second insulating layer 102 may include, for example, silicon nitride (SiN). Although each of the first insulating layer 101 and the second insulating layer 102 is illustrated as being alternately stacked twice, the inventive concept is not limited thereto, and each of the first insulating layer 101 and the second insulating layer 102 may be formed once or at least three times.

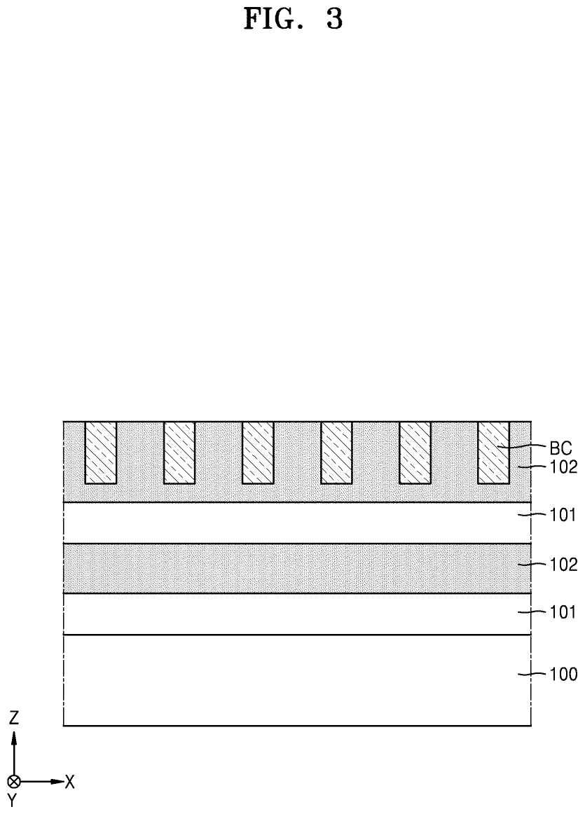

Referring to FIG. 3, a plurality of contacts BC may be formed in an uppermost one of the second insulating layers 102. The plurality of contacts BC may be apart from each other in a first direction (X direction) and a second direction (Y direction) and arranged in a matrix form. An upper surface (e.g., a top surface) of each of the contacts BC may be at the same vertical level as an upper surface (e.g., a top surface) of the uppermost one of the second insulating layers 102. For example, the upper surface of the contact BC may be coplanar with the upper surface of the uppermost one of the second insulating layers 102. A lower surface (e.g., a bottom surface) of each of the contacts BC may be at a higher vertical level than a lower surface (e.g., a bottom surface) of the uppermost one of the second insulating layers 102. That is, the contacts BC may not contact the first insulating layer 101 (the first insulating layer 101 below the uppermost one of the second insulating layers 102).

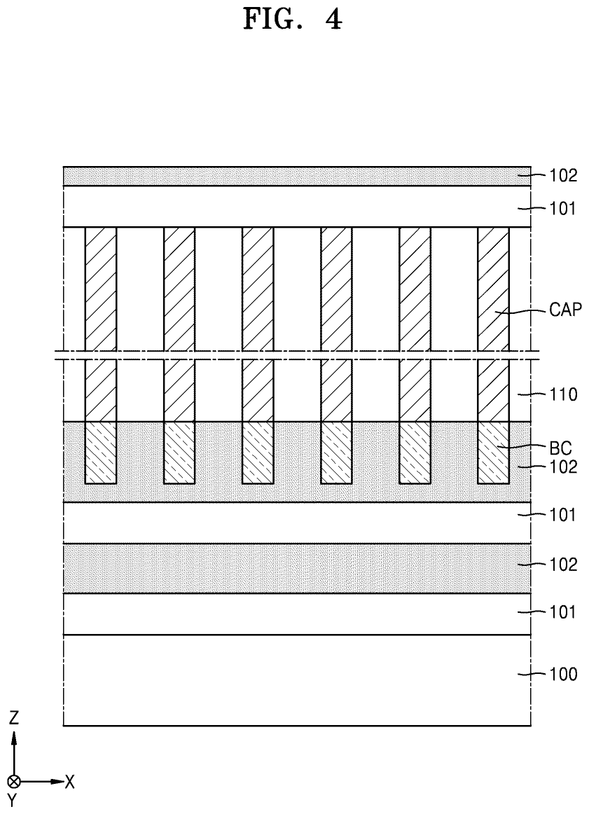

Referring to FIG. 4, a plurality of capacitor structures CAP may be formed on the resultant structure of FIG. 3. The plurality of capacitor structures CAP may respectively overlap the plurality of contacts BC in a third direction (Z direction). Although the plurality of capacitor structures CAP are illustrated as being entirely aligned with the contacts BC in the third direction (Z direction) in FIG. 4, the inventive concept is not limited to the illustration. Only at least some of the capacitor structures CAP may be (electrically) connected to only at least some of the contacts BC in the third direction (Z direction).

Respective spaces between the plurality of capacitor structures CAP may be (at least partially) filled by a lower insulating film 110, and the first insulating layer 101 and the second insulating layer 102 may be provided again on the plurality of capacitor structures CAP. Although each of the first insulating layer 101 and the second insulating layer 102 is illustrated as being formed once, the number of times each of the first insulating layer 101 and the second insulating layer 102 is stacked is not limited.

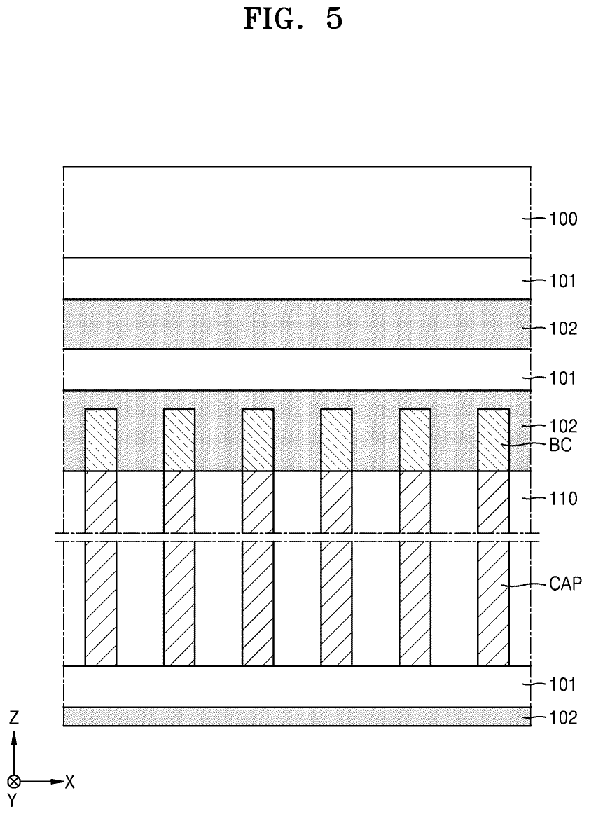

Next, referring to FIG. 5, the resultant structure of FIG. 4 may be reversed (flipped upside down). As a result, although the capacitor structures CAP are illustrated as being on the contact BC in FIG. 4, the contact BC may be illustrated as being on the capacitor structures CAP in FIGS. 5 to 19.

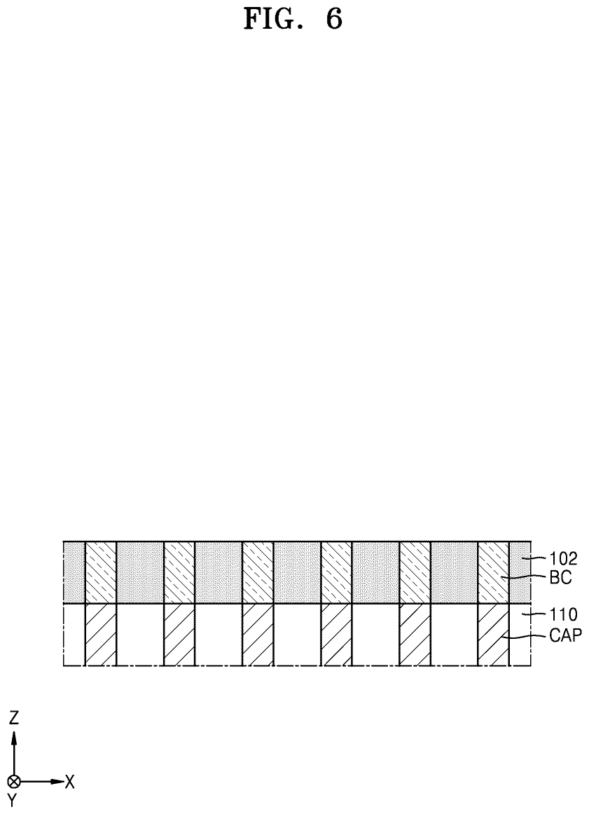

Thereafter, the first substrate 100, the first insulating layer 101, and the second insulating layer 102 may be removed. In some embodiments, the removal of the first substrate 100, the first insulating layer 101, and the second insulating layer 102 may be performed by using a chemical mechanical polishing (CMP) process. During the removal of the first substrate 100, a plurality of first insulating layers 101, and a plurality of second insulating layers 102, the second insulating layer 102 including the contacts BC may not completely removed. However, the second insulating layer 102 including the contacts BC may be etched (at least partially removed) by using a CMP process so that the upper surfaces (e.g., the top surfaces) of the contacts BC may be exposed. The resultant structure obtained after the CMP process is completed may be understood with reference to the cross-sectional view of FIG. 6.

Only an upper portion of the capacitor structures CAP is illustrated in FIGS. 6 to 19 for brevity.

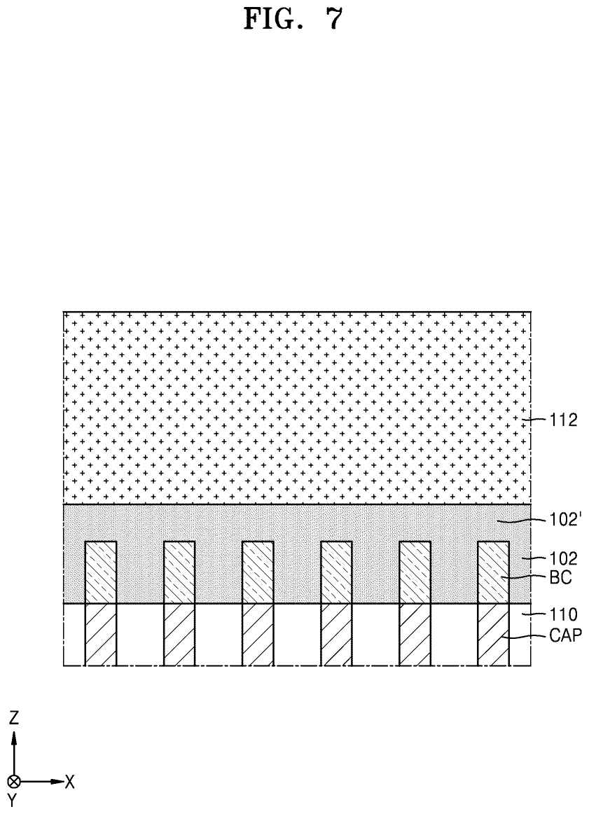

Thereafter, referring to FIG. 7, an additional insulating layer 102′ may be formed on the second insulating layer 102, and a first interlayer insulating film 112 may be formed on the additional insulating layer 102′.

In embodiments, the additional insulating layer 102′ may include SiN. For example, the additional insulating layer 102′ may include (substantially) the same material as the second insulating layer 102. That is, the additional insulating layer 102′ may be integrally formed with the second insulating layer 102. The description of “integrally formed”, “integrally connected”, and the like herein may refer to a unitary structure that does not include a (visible) boundary between the sub-structures therein. For example, the second insulating layer 102 and the additional insulating layer 102′ may not have a visible boundary therebetween as they are formed of the same material(s).

In embodiments, the first interlayer insulating film 112 may include, for example, silicon oxide, silicon oxynitride, silicon nitride, and/or a low-k dielectric material having a lower dielectric constant than silicon oxide, without being limited thereto.

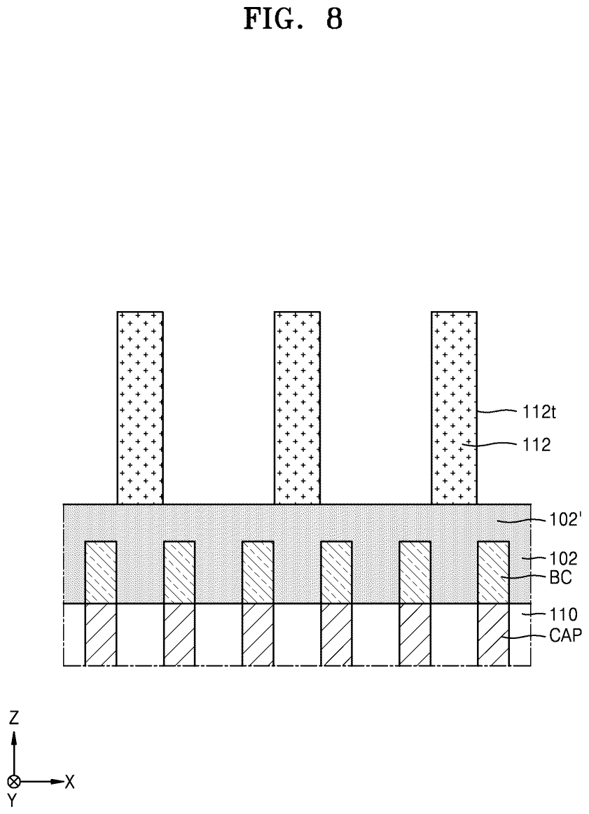

Referring to FIG. 8, a portion of the first interlayer insulating film 112 may be etched to form a cell trench 112t. A plurality of cell trenches 112t may extend in the second direction (Y direction) and be (equidistantly) apart from each other in the first direction (X direction). In some embodiments, the cell trenches 112t may be arranged to be spaced apart from each other by an equal (e.g., a substantially equal) distance in the first direction (X direction). Thus, the first interlayer insulating film 112 may form fin-type insulating patterns, which each extend in the second direction (Y direction) and are apart from each other by the cell trench 112t.

In some embodiments, an upper surface (e.g., a top surface) of the additional insulating layer 102′ may be exposed by the cell trench 112t.

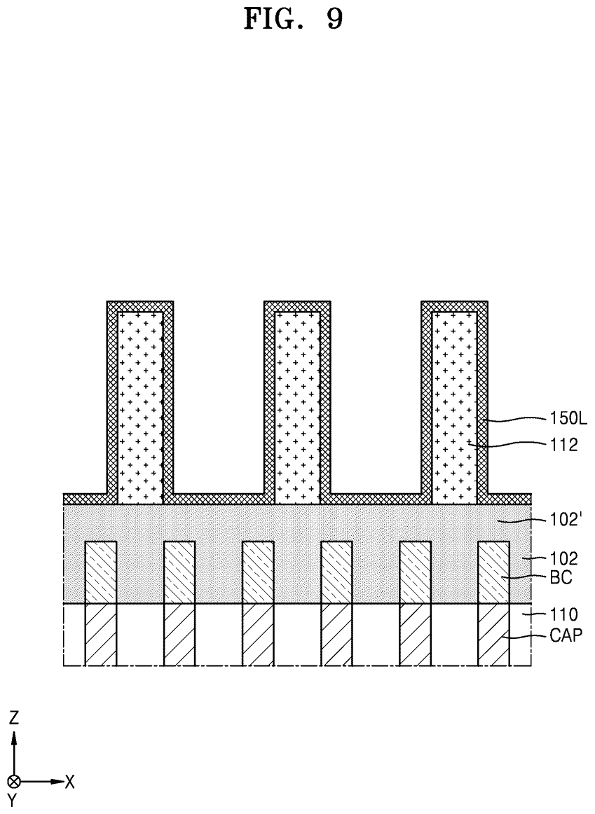

Referring to FIG. 9, a preliminary gate electrode layer 150L may be formed inside the cell trench 112t. For example, the preliminary gate electrode layer 150L may extend along a lower surface (e.g., a bottom surface) and a side surface of the cell trench 112t. For example, the preliminary gate electrode layer 150L may be on (may extend along) an upper surface (e.g., a top surface) of the additional insulating layer 102′ and a side surface of the first interlayer insulating film 112 (a side surface of the fin-type insulating pattern). The preliminary gate electrode layer 150L may be on an upper surface (e.g., a top surface) of the first interlayer insulating film 112. The preliminary gate electrode layer 150L may conformally cover the upper surface (e.g., the top surface) of the first interlayer insulating film 112. In embodiments, a side surface and the upper surface (e.g., the top surface) of the first interlayer insulating film 112 and the upper surface (e.g., the top surface) of the additional insulating layer 102′ may be entirely covered by the preliminary gate electrode layer 150L.

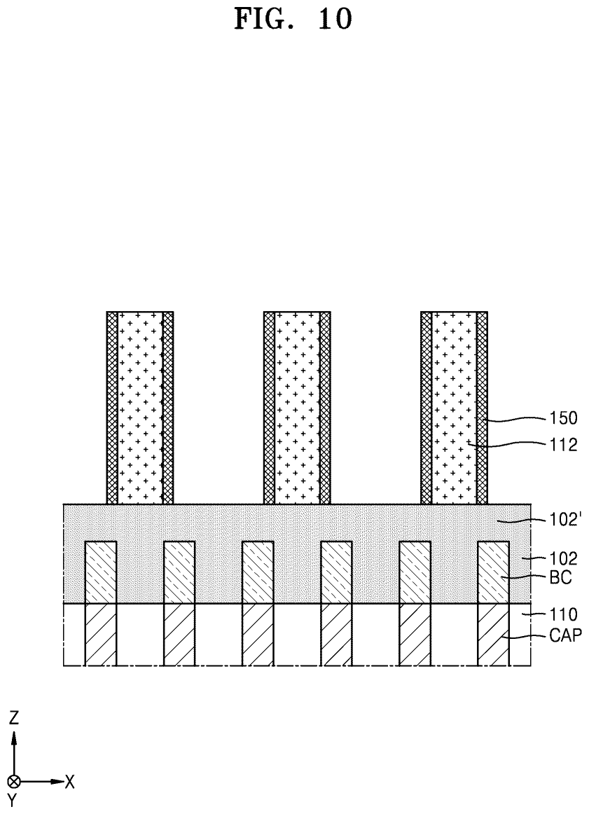

Referring to FIG. 10, a portion of the preliminary gate electrode layer 150L may be removed to form a gate electrode 150. The gate electrode 150 may be formed to expose the upper surface (e.g., the top surface) of the first interlayer insulating film 112 and the upper surface (e.g., the top surface) of the additional insulating layer 102′. For example, a planarization process may be performed to expose the upper surface (e.g., the top surface) of the first interlayer insulating film 112 and the upper surface (e.g., the top surface) of the additional insulating layer 102′. The planarization process may include a CMP process, without being limited thereto.

In embodiments, by removing the portion of the preliminary gate electrode layer 150L, the gate electrode 150 may be left in the form of a vertical bar that extends around (e.g., at least partially surrounds) both (opposite) sidewalls of the first interlayer insulating film 112 and extends in the third direction (Z direction).

The upper surface (e.g., the top surface) of the gate electrode 150 may be at the same vertical level as the upper surface (e.g., the top surface) of the first interlayer insulating film 112. For example, the upper surface of the gate electrode 150 may be coplanar with the upper surface of the first interlayer insulating film 112.

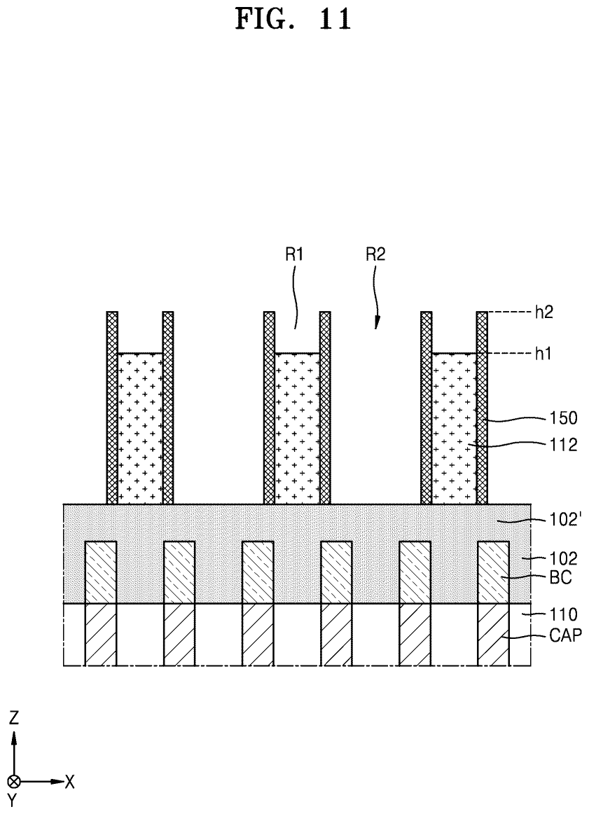

Referring to FIG. 11, an upper portion of the first interlayer insulating film 112 may be removed to form a first recess R1 between the first interlayer insulating film 112 and a pair of gate electrodes 150. To distinguish from the first recess R1, a space among one gate electrode 150, another gate electrode 150, which is not opposite to the one gate electrode 150 with the first interlayer insulating film 112 therebetween, and the additional insulating layer 102′ may be referred to as a second recess R2. For example, adjacent gate electrodes 150 may be spaced apart from each other by the first recess R1 and the first interlayer insulating film 112 (in the first direction (X direction)) or by the second recess R2 (in the first direction (X direction)).

In embodiments, an upper portion of the first interlayer insulating film 112 may be removed using an etching process. After the etching process is performed, a first height h1, which is a height of the upper surface (e.g., the top surface) of the first interlayer insulating film 112, may be lower (less) than a second height h2, which is a height of the upper surface (e.g., the top surface) of the gate electrode 150.

In embodiments, a difference between the second height h2 and the first height h1, which corresponds to a depth by which the upper portion of the first interlayer insulating film 112 is removed, may be (about) half of a length of the first interlayer insulating film 112 in the third direction (Z direction) before the upper portion of the first interlayer insulating film 112 is removed. However, the inventive concept is not limited thereto, and a difference between the second height h2 and the first height h1 may be less than the length of the first interlayer insulating film 112 in the third direction (Z direction) before the upper portion of the first interlayer insulating film 112 is removed. A length of the remaining portion of the first interlayer insulating film 112 in the third direction (Z direction) after the upper portion of the first interlayer insulating film 112 is removed may be greater than or equal to the half of the length of the first interlayer insulating film 112 in the third direction (Z direction) before the first interlayer insulating film 112 is removed. In some embodiments, the difference between the second height h2 and the first height h1 may be (substantially) equal to or less than (about) half of a length of the gate electrode 150 in the third direction (Z direction).

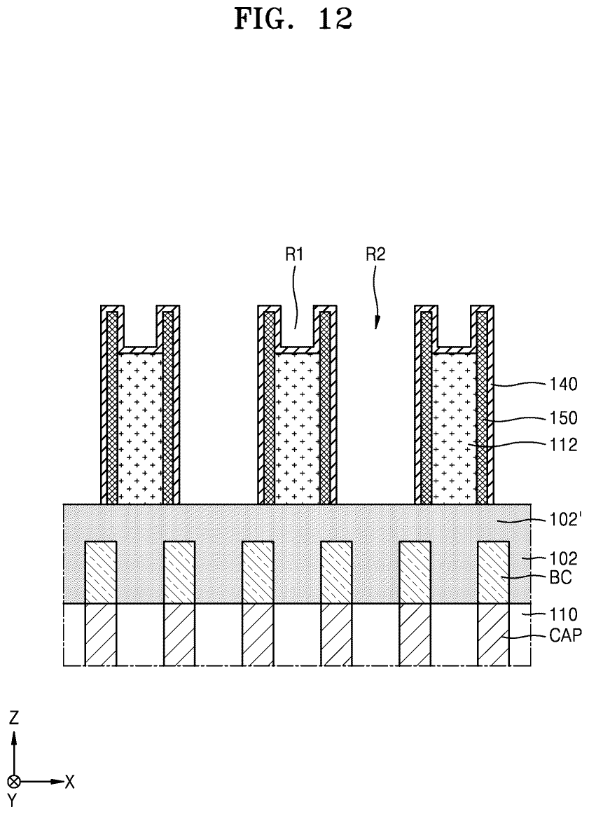

Subsequently, referring to FIG. 12, a gate insulating layer 140 may be formed on the gate electrodes 150. The gate insulating layer 140 may be on the first interlayer insulating film 112 and (the upper surface of) the additional insulating layer 102′.

The gate insulating layer 140 may be (e.g., may extend to conformally extend around (e.g., surround)) the upper surface (e.g., the top surface) and a side surface of each of the gate electrodes 150 and the upper surface (e.g., the top surface) of the first interlayer insulating film 112. For example, the gate insulating layer 140 may conformally extend along profiles of a side surface and a lower surface (e.g., a bottom surface) of the first recess R1 and a side surface of the second recess R2. The gate insulating layer 140 may be on the lower surface (e.g., the bottom surface) of the second recess R2.

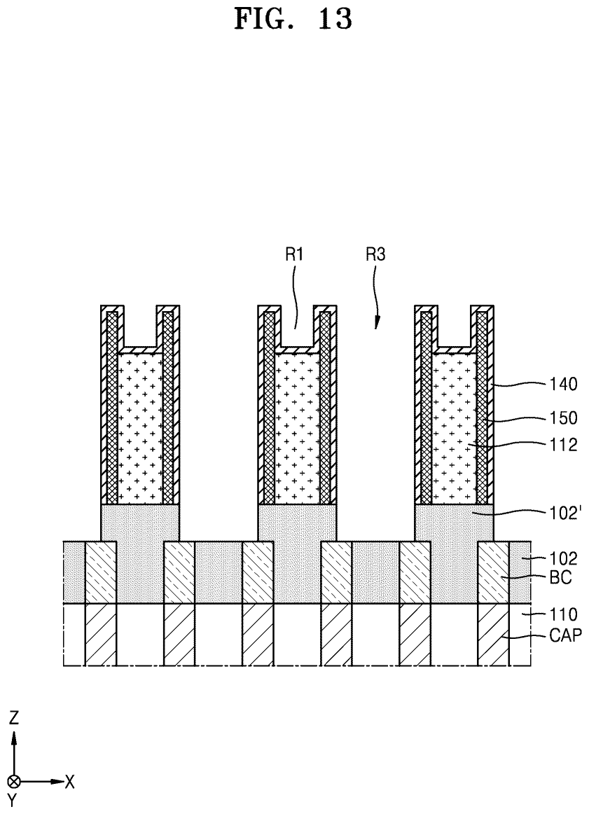

Referring to FIG. 13, a portion of the additional insulating layer 102′ may be etched. More specifically, a portion of the additional insulating layer 102′, which is exposed between the second recesses (refer to R2 in FIG. 12), may be etched, and thus, the upper surface (e.g., the top surface) of the second insulating layer 102 may be exposed. As a result, a third recess R3 may be newly formed in a place where the second recess (refer to R2 in FIG. 12) was located. The additional insulating layer 102′, which has extended in the first direction (X direction), may be left in the form of a plurality of islands (spaced apart from each other in the first direction (X direction)) due to the etching process. After the portion of the additional insulating layer 102′ is etched, portions of upper surfaces (e.g., top surfaces) of a plurality of contacts BC may be (at least partially) exposed.

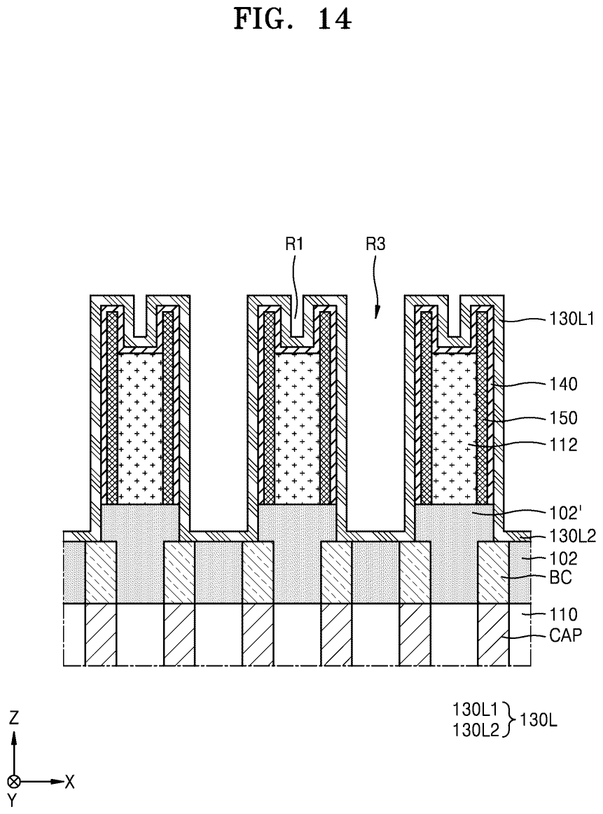

Referring to FIG. 14, a preliminary channel layer 130L may be (stacked) on the gate insulating layer 140. For example, the preliminary channel layer 130L may extend along the gate electrodes 150 and the gate insulating layer 140. In addition, the preliminary channel layer 130L may extend on a sidewall of the additional insulating layer 102′, the exposed upper surfaces (e.g., top surfaces) of the contacts BC, and/or upper surfaces of the second insulating layer 102. The preliminary channel layer 130L may be formed using, for example, an atomic layer deposition (ALD) process, without being limited thereto.

The preliminary channel layer 130L may include a first preliminary channel layer 130L1 and a second preliminary channel layer 130L2. The first preliminary channel layer 130L1 may be on (e.g., cover) the lower surface (e.g., the bottom surface) and side surfaces of the first recess R1, exposed surfaces of the gate insulating layer 140, a side surface of the additional insulating layer 102′, and exposed surfaces of the contact BC. The second preliminary channel layer 130L2 may be on (e.g., cover) a lower portion of the third recess R3. For example, the second preliminary channel layer 130L2 may be on the second insulating layer 102. The first preliminary channel layer 130L1 and the second preliminary channel layer 130L2 may include (substantially) the same material and may be formed using the same process and integrally connected to each other.

Referring to FIG. 13, because the top surfaces of the plurality of contacts BC are exposed when the portion of the additional insulating layer 102′ is etched, the first preliminary channel layer 130L1 may be connected (in contact with) to the upper surfaces (e.g., the top surfaces) of the plurality of contacts BC.

The preliminary channel layer 130L may include a semiconductor material. As an example, the preliminary channel layer 130L may include an oxide semiconductor material. In some embodiments, the preliminary channel layer 130L may include an elemental semiconductor material, such as silicon (Si) and germanium (Ge), or a doped elemental semiconductor material. In some embodiments, the preliminary channel layer 130L may include a Group IV-IV compound semiconductor and/or a Group III-V compound semiconductor. The preliminary channel layer 130L may include a 2D semiconductor material. The preliminary channel layer 130L may include a single layer or multiple layer of the semiconductor materials described above. For example, the preliminary channel layer 130L may include IGZO.

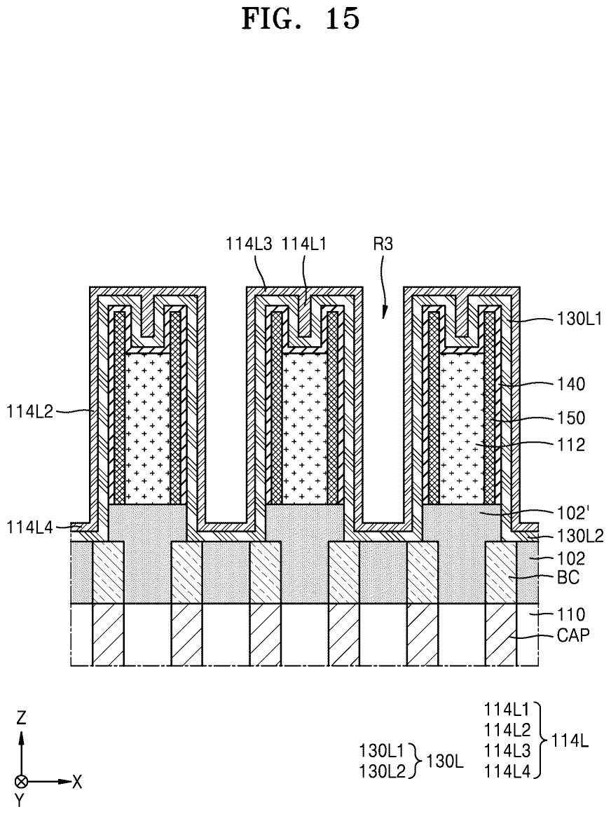

Referring to FIG. 15, a preliminary second interlayer insulating film 114L may be formed.

The preliminary second interlayer insulating film 114L may include a first preliminary second interlayer insulating film 114L1, a second preliminary second interlayer insulating film 114L2, a third preliminary second interlayer insulating film 114L3, and a fourth preliminary second interlayer insulating film 114L4. The first preliminary second interlayer insulating film 114L1 may (at least partially) fill the first recess (refer to R1 in FIG. 14). The second preliminary second interlayer insulating film 114L2 may extend in the third direction (Z direction) and extend around (e.g., surround) sidewalls of the preliminary channel layer 130L (e.g., the first preliminary channel layer 130L1). The third preliminary second interlayer insulating film 114L3 may be on (e.g., may cover or may be connected to) an upper surface (e.g., a top surface) of the first preliminary second interlayer insulating film 114L1 and upper surface (e.g., uppermost surface) of the preliminary channel layer 130L (e.g., the first preliminary channel layer 130L1). The fourth preliminary second interlayer insulating film 114L4 may be on (e.g., may cover) a lower surface (e.g., a bottom surface) of the third recess R3. For example, the fourth preliminary second interlayer insulating film 114L4 may be on (may cover) an upper surface of the preliminary channel layer 130L (e.g., an upper surface of the second preliminary channel layer 130L2).

In embodiments, the preliminary second interlayer insulating film 114L may entirely fill the first recess (refer to R1 in FIG. 14) and entirely cover the lower surface (e.g., the bottom surface) and a side surface of the third recess R3.

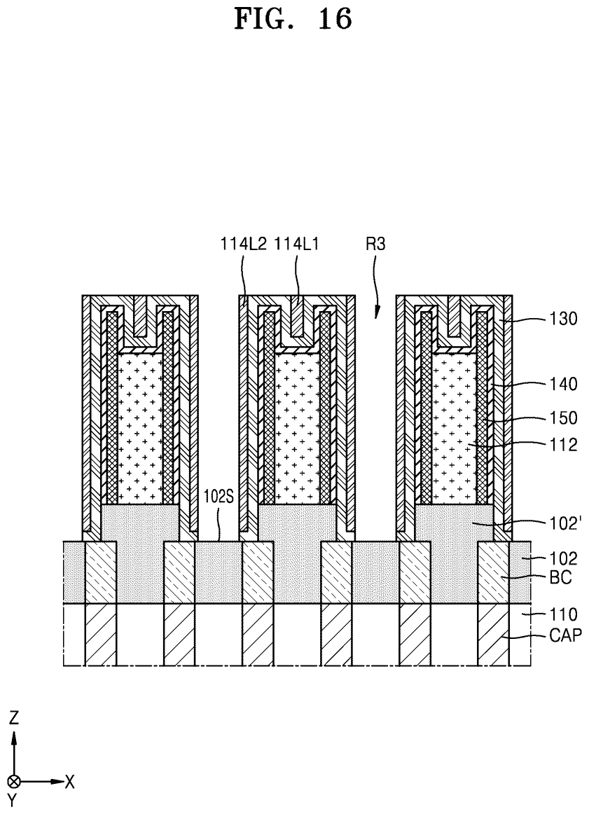

Next, referring to FIG. 16, portions of the preliminary second interlayer insulating film 114L and the preliminary channel layer 130L may be removed to form the first preliminary second interlayer insulating film 114L1, the second preliminary second interlayer insulating film 114L2, and a channel layer 130.

In embodiments, the removal of the portions of the preliminary second interlayer insulating film 114L and the preliminary channel layer 130L may be performed by using an etchback process. Due to the etchback process, the third preliminary second interlayer insulating film 114L3 may be removed, and thus, an uppermost surface of the preliminary second interlayer insulating film 114L may be at the same vertical level as an uppermost surface of the channel layer 130. Due to the etchback process, the fourth preliminary second interlayer insulating film 114L4 and the second preliminary channel layer 130L2 may be removed, and thus, a portion of an upper surface (e.g., a top surface) 102S of the second insulating layer 102 may be exposed in the third recesses R3. During the etchback process, the preliminary channel layer 130L that includes the first preliminary channel layer 130L1 and the second preliminary channel layer 130L2, which extend in the first direction (X direction) and are integrally connected to each other, may be separated into a plurality of channel layers 130, which are a predetermined distance apart from each other in the first direction (X direction). For example, at least a portion of the second preliminary channel layer 130L2 may be removed to form the channel layers 130 spaced apart from each other in the first direction (X direction).

Next, due to an annealing process, oxygen may be supplied to the channel layer 130 through the preliminary second interlayer insulating film 114L.

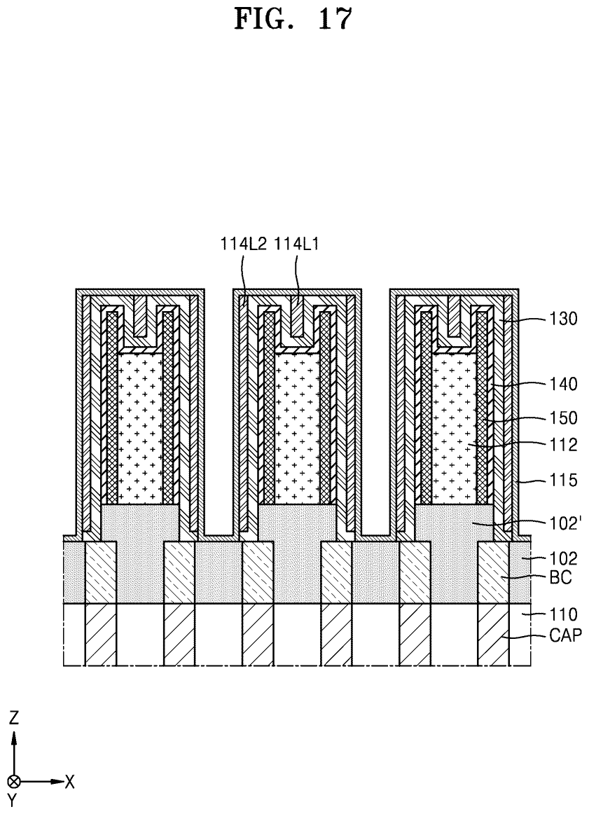

Referring to FIG. 17, a capping insulating film 115 may be formed on (to conformally cover) the resultant structure of FIG. 16. The capping insulating film 115 may be formed to ensure the reliability of the IC device 10 after the annealing process is completed.

In embodiments, the capping insulating film 115 may include aluminum oxide (AIO). The capping insulating film 115 may entirely cover the uppermost surface of the channel layer 130 and the uppermost surface of the first preliminary second interlayer insulating film 114L1 (and the uppermost surface of the second preliminary second interlayer insulating film 114L2), extend along sidewalls of the second preliminary second interlayer insulating film 114L2 (and sidewalls of the channel layer 130), and entirely cover the lower surface (e.g., the bottom surface) and side surfaces of the third recess R3. The upper surface (e.g., the top surface) 102S of the second insulating layer 102 may also be covered by the capping insulating film 115.

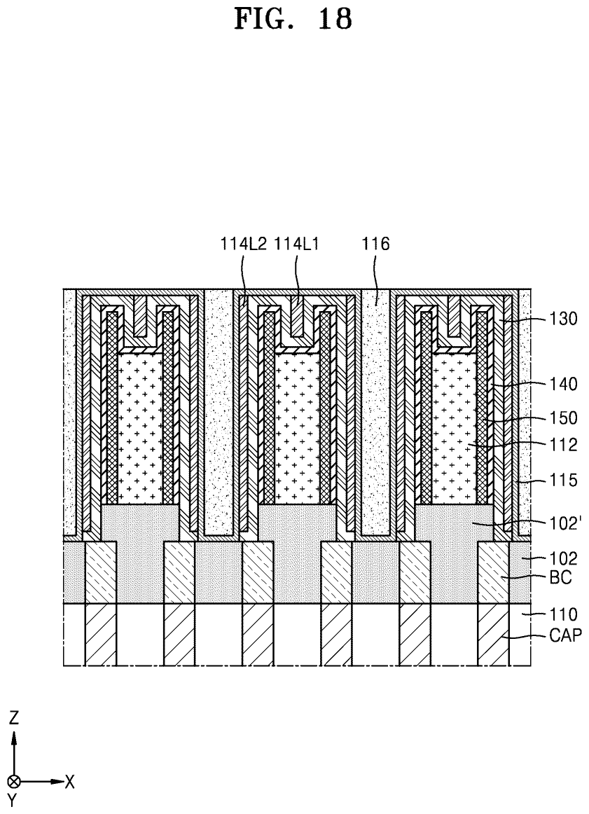

Referring to FIG. 18, a third interlayer insulating film 116 may be formed to (at least partially) fill the third recess (refer to R3 in FIG. 17).

The third interlayer insulating film 116 may include, for example, silicon oxide, silicon oxynitride, silicon nitride, and/or a low-k dielectric material having a lower dielectric constant than silicon oxide, without being limited thereto.

In embodiments, the third interlayer insulating film 116 may be formed to entirely cover the third recess (refer to R3 in FIG. 17) and an upper surface (e.g., a top surface) of the capping insulating film 115 and be planarized such that the upper surface (e.g., the top surface) of the capping insulating film 115 is exposed. Thus, the third interlayer insulating film 116 may be obtained in a form shown in FIG. 18. For example, the upper surface of the capping insulating film 115 may be coplanar with the upper surface of the third interlayer insulating film 116.

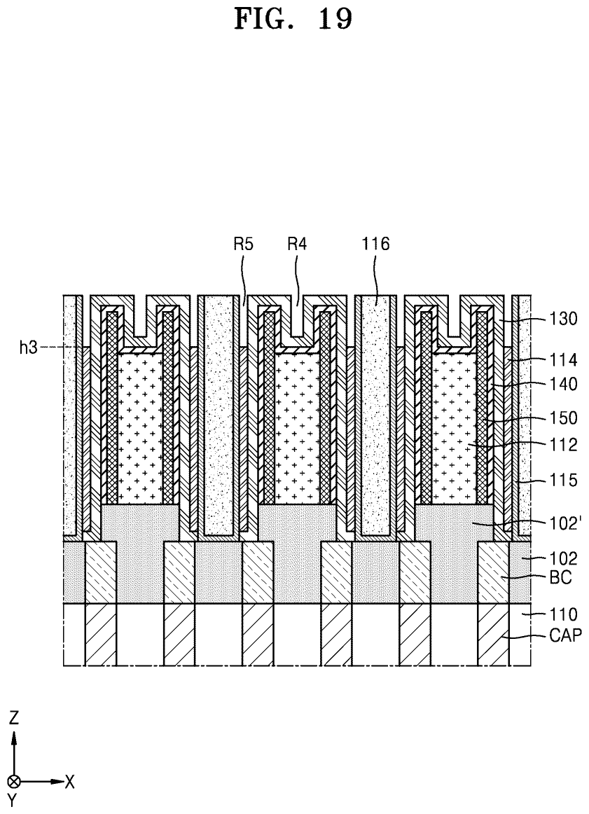

Referring to FIG. 19, upper portions of the capping insulating film 115 may be removed, and a portion of the preliminary second interlayer insulating film 114L (e.g., the first preliminary second interlayer insulating film 114L1 and an upper portion of the second preliminary second interlayer insulating film 114L2) may be removed to obtain the second interlayer insulating film 114.

In embodiments, the upper portion of the capping insulating film 115 may be removed using an etchback process. By removing the capping insulating film 115, an upper surface (e.g., a top surface) of the channel layer 130 and an upper surface (e.g., a top surface) of the preliminary second interlayer insulating film 114L may be exposed.

After a portion (e.g., the upper portion) of the capping insulating film 115 is removed, the first preliminary second interlayer insulating film 114L1 filling the first recess (refer to R1 in FIG. 14) may be removed to form a fourth recess R4, and an upper portion of the second preliminary second interlayer insulating film 114L2 may be removed. As a result, a fifth recess R5 may be formed as shown in FIG. 19.

A third height h3, which is a length (or a height of an upper surface) of the remaining portion of the second interlayer insulating film 114 in the third direction (Z direction), may be greater (or higher) than the first height (refer to h1 in FIG. 11), which is a length (or a height of an upper surface) of the first interlayer insulating film 112 in the third direction (Z direction). However, the inventive concept is not limited thereto, and the third height h3 may be less (or lower) than the first height (refer to h1 in FIG. 11) or be equal to (or coplanar with) the first height (refer to h1 in FIG. 11). That is, a relative relationship (e.g., a length difference or a height difference, if any) between the first height (refer to h1 in FIG. 11) and the third height h3 may not affect the scope of the inventive concept.

Next, referring back to FIG. 1, in the resultant structure of FIG. 19, a conductive line 120, which extends in the first direction (X direction), may be formed to (at least partially) fill both the fourth recess R4 and the fifth recess R5 and entirely cover the upper surface (e.g., the top surface) of each of the channel layer 130, the capping insulating film 115, and the third interlayer insulating film 116. In some embodiments, a lower surface (e.g., a bottom surface) of the conductive line 120 may be lower than the upper surface (e.g., top surface) of the first interlayer insulating film 112 in the third direction (Z direction). However, the embodiments are not limited thereto. For example, the lower surface (e.g., the bottom surface) of the conductive line 120 may be equal to or higher than the upper surface (e.g., top surface) of the first interlayer insulating film 112 in the third direction (Z direction). In some embodiments, the lowermost surface (the bottom surface) of the conductive line 120 may be defined by the fifth recess R5.

The conductive line 120 may include, for example, doped polysilicon, a metal, a conductive metal nitride, a conductive metal silicide, a conductive metal oxide, and/or a combination thereof. Although the conductive line 120 is illustrated as being formed as a single layer, the conductive line 120 may be formed as a multiple layer in some embodiments.

The IC device 10 of FIG. 1 may be obtained using the method described above with reference to FIGS. 2 to 19.

Referring to FIG. 1 together, the IC device 10 according to the embodiments may be manufactured such that a sectional shape formed by the first interlayer insulating film 112, the gate electrode 150, and the channel layer 130 is not rectangular but includes a rough portion (protruding (upwardly) in the third direction (Z direction)). Thus, the IC device 10 may easily ensure contact area in the third direction (Z direction). Accordingly, IC devices with improved electrical reliability may be obtained. Furthermore, before the channel layer 130 is formed, a capacitor structure CAP may be first formed, and the conductive line 120 may be formed on the channel layer 130, and thus, an improvement in contact resistance of a bit line may also be expected.

While the inventive concept has been particularly shown and described with reference to embodiments thereof, it will be understood that various changes in form and details may be made therein without departing from the scope of the following claims.

What is claimed is:

1. An integrated circuit device comprising:
an insulating layer;
contacts in the insulating layer, wherein the contacts are spaced apart from each other by a predetermined distance in a first direction;
a cell trench extending in the insulating layer, wherein the cell trench extends in a second direction that intersects the first direction;
an interlayer insulating film adjacent the cell trench;
a pair of gate electrodes that are respectively in contact with opposite sidewalls of the interlayer insulating film in the first direction;
a channel layer in the cell trench, wherein the channel layer extends around the pair of gate electrodes;
a gate insulating layer between the channel layer and the pair of gate electrodes; and
a conductive line on the channel layer, wherein the conductive line extends in the first direction and is in contact with the channel layer,
wherein an upper surface of the pair of gate electrodes is at a first distance from an upper surface of the insulating layer in a third direction that intersects the first direction and the second direction,
wherein an upper surface of the interlayer insulating film is at a second distance from the upper surface of the insulating layer in the third direction, and
wherein the first distance is different from the second distance.

2. The integrated circuit device of claim 1, wherein the first distance is farther than the second distance from the upper surface of the insulating layer in the third direction.

3. The integrated circuit device of claim 1, wherein the gate insulating layer is on the upper surface of the interlayer insulating film.

4. The integrated circuit device of claim 1, wherein a portion of the channel layer is between the upper surface of the interlayer insulating film and the conductive line.

5. The integrated circuit device of claim 1, wherein the channel layer comprises a portion that protrudes in the third direction.

6. The integrated circuit device of claim 1, wherein the channel layer includes an oxide semiconductor material.

7. The integrated circuit device of claim 6, wherein the oxide semiconductor material includes indium gallium zinc oxide (IGZO).

8. The integrated circuit device of claim 1, wherein a lowermost surface of the conductive line is closer than the upper surface of the pair of gate electrodes to the upper surface of the insulating layer in the third direction.

9. The integrated circuit device of claim 1, wherein the channel layer is on an upper surface of the contacts, and
wherein the channel layer is electrically connected to the contacts, and
wherein a lower surface of the contacts is electrically connected to a capacitor structure.

10. The integrated circuit device of claim 1, wherein a difference between the first distance and the second distance is less than half of a length of at least one from among the pair of gate electrodes in the third direction.

11. The integrated circuit device of claim 1, wherein a difference between the first distance and the second distance is equal to half of a length of at least one from among the pair of gate electrodes in the third direction.

12. The integrated circuit device of claim 1, wherein a lowermost surface of the conductive line is closer than the upper surface of the interlayer insulating film to the upper surface of the insulating layer in the third direction.

13. The integrated circuit device of claim 1, wherein a lowermost surface of the conductive line is farther than or at a same distance as the upper surface of the interlayer insulating film from the upper surface of the insulating layer in the third direction.

14. An integrated circuit device comprising:
an insulating layer;
interlayer insulating films on the insulating layer, wherein the interlayer insulating films are spaced apart from each other in a first direction and extend in a second direction that intersects the first direction;
a pair of gate electrodes that are spaced apart each other in the first direction on the insulating layer, wherein an interlayer insulating film from among the interlayer insulating films is between the pair of gate electrodes;
a gate insulating layer on an upper surface of the interlayer insulating film and an upper surface and a sidewall of the pair of gate electrodes;
a channel layer extending along at least a portion of the gate insulating layer with a uniform thickness; and
a conductive line on the channel layer, wherein the conductive line extends in the first direction and is in contact with the channel layer,
wherein at least one from among the pair of gate electrodes comprises a first portion and a second portion,
wherein the first portion has a bar shape and is in direct contact with a sidewall of the interlayer insulating film,
wherein the second portion is integrally connected to the first portion, and
wherein the second portion extends farther than the upper surface of the interlayer insulating film from an upper surface of the insulating layer in a third direction that intersects the first direction and the second direction.

15. The integrated circuit device of claim 14, wherein the channel layer comprises an oxide semiconductor material.

16. The integrated circuit device of claim 14, wherein a lowermost surface of the conductive line is closer than an upper surface of the second portion.

17. The integrated circuit device of claim 14, further comprising:
contacts spaced apart from each other by a predetermined distance in the first direction,
wherein an upper surface of each of the contacts is closer than a lower surface of the interlayer insulating film to a lower surface of the insulating layer in the third direction, and
wherein the upper surface of each of the contacts is electrically connected to the channel layer, and a lower surface of each of the contacts is electrically connected to a capacitor structure on the lower surface of the insulating layer.

18. The integrated circuit device of claim 14, wherein a length of the first portion in the third direction is greater than a length of the second portion in the third direction.

19. An integrated circuit device comprising:
an insulating layer;
interlayer insulating films on the insulating layer, wherein the interlayer insulating films are spaced apart from each other in a first direction and extend in a second direction that intersects the first direction;
contacts in the insulating layer, wherein the contacts are spaced apart from each other in the first direction;
a pair of gate electrodes that are spaced apart from each other in the first direction on the insulating layer, wherein an interlayer insulating film from among the interlayer insulating films is between the pair of gate electrodes;
a gate insulating layer on an upper surface of the interlayer insulating film and an upper surface and a sidewall of the pair of gate electrodes;
a channel layer extending along at least a portion of the gate insulating layer with a uniform thickness, wherein the channel layer is in contact with at least a portion of an upper surface of each of the contacts; and
a conductive line on the channel layer, wherein the conductive line extends in the first direction and is in contact with the channel layer,
wherein the channel layer comprises an oxide semiconductor material,
wherein a length of at least one from among the pair of gate electrodes in a third direction is greater than a length of the interlayer insulating film in the third direction, and
wherein the third direction intersects the first direction and the second direction.

20. The integrated circuit device of claim 19, wherein the length of the at least one from among the pair of gate electrodes in the third direction is equal to or less than twice the length of the interlayer insulating film in the third direction.
